(19) United States
(12) Patent Application Publication
(10) Pub. No.: US 2025/0272816 A1
(43) Pub. Date: Aug. 28, 2025

(54) METHOD AND DEVICE FOR OPTICAL QUALITY CONTROL DURING THE MANUFACTURE OF CIRCUIT BOARDS

(71) Applicant: SIEMENS AKTIENGESELLSCHAFT, München (DE)

(72) Inventors: Daniel Fiebag, Ingolstadt (DE); Alexis Guibourgé, München (DE); Marcel Kuhn, Augsburg (DE); Ulrike Dowie, Neubiberg (DE)

(21) Appl. No.: 18/268,405

(22) PCT Filed: Nov. 12, 2021
(86) PCT No.: PCT/EP2021/081448

§ 371 Date: Jun. 20, 2023

(30) Foreign Application Priority Data
Dec. 23, 2020 (EP) 20216995.9

(51) Int. Cl. G06T 7/00; G01N 21/88; G06V 10/72; G06V 10/764; G06V 10/774

(52) U.S. Cl. CPC G06T 7/0004; G01N 21/8851; G06V 10/764; G06V 10/774; G01N 2021/8887; G06T 2207/10024; G06T 2207/20081; G06T 2207/20084; G06T 2207/30141; G06T 2207/30152; G06V 10/72

(57) ABSTRACT

The invention relates to a method for optical quality control (Q) during the manufacture (1) of circuit boards (L), comprising: capturing (S3) an image (P1) of a circuit board (L); determining (S4) a first defect indicator (F1) by means of optical image processing on the basis of the captured image; determining (S5) a second defect indicator (F2) by means of a trained adaptive algorithm (ML) on the basis of the captured image (P1), wherein, if the first defect indicator (F1) determined by means of the optical image processing (OR) indicates that the circuit board (L) is defective (S41), the second defect indicator (F2) is determined by means of the trained adaptive algorithm (ML) (S5); outputting (S6) the second defect indicator (F2) instead of the first defect indicator (F1) as the result of the quality control (Q).

### CROSS REFERENCE TO RELATED APPLICATIONS

This present patent document is a § 371 nationalization of PCT Application Serial Number PCT/EP2021/081448, filed Nov. 12, 2021, designating the United States, which is hereby incorporated in its entirety by reference. This patent document also claims the benefit of EP20216995.9 filed on Dec. 23, 2020 which is hereby incorporated in its entirety by reference.

### BACKGROUND

A method for checking a circuit board or a circuit board subassembly is already known from the European patent application bearing filing number EP 20185488.2.

In power electronics, electrical components BT1, BT2, BT3 in through-hole technology (THT) are electrically and mechanically connected to the circuit board L, as shown in FIG. 1. In most cases the electrical components are inserted into receiving holes on the circuit board L at a population station B, such as for example a manual population station or with the help of a population robot. The circuit board L travels together with the inserted electrical components BT1, BT2, BT3 into a wave soldering machine W, where it is drawn over a wave of solder, wherein tin forms an electrically conductive connection between the circuit board L and the electrical components BT1, BT2, BT3. After the soldering process the contact points (hereinafter referred to as soldering points) and the form thereof are inspected optically by an inspection system for quality control. Automatic optical inspections (for short: AOIs) are in most cases used for this, as shown in FIG. 1. The inspection system in this case includes hardware components for optical image processing, such as camera, computer and illumination. Potential defects that the AOI is to detect are missing components, misaligned elements, soldering points with insufficient wetting (cold or open soldering point), or solder bridges, in other words electrical contacts of soldering points which should have electrical potential.

By the optical inspection an image P1 is in this case captured using image capture. This is evaluated by software in the AOI software, i.e., by optical image processing OR. To this end, an inspection and test program is stored for each product, for example including a circuit board L and components BT1, BT2, BT3. If the optical image processing OR finds one or more defects on a circuit board L, this is supplied and presented to an operator O via a return section, for example at a diagnostic station T, for manual diagnosis. The operator O on site now carries out a manual visual check, for example via a display unit A on a diagnostic dashboard. Using a diagnostic keyboard T1, for example likewise on a diagnostic dashboard, the operator O may now enter the real diagnosis. The result of the diagnosis may be stored in a database DB. However, in accordance with the form of embodiment in FIG. 1 the result of the diagnosis is not fed back to the AOI software, for example to the optical image processing OR thereof. A test engineer would hence have to maintain and oversee the inspection and test programs of the AOI software or of the optical image processing OR manually. For example, if there are changes in the lighting conditions or changes by the circuit board manufacturer to the circuit board or other influences concerning the manufacture of the circuit board(s), corresponding changes would have to be made to one or more of the inspection and test programs used or to the optical image processing OR used. However, the test engineer is not automatically notified of any of the aforementioned changes and influences.

Patent publication CN112102242A discloses a method for detecting PCB components on the basis of a lightweight network. The method includes the following steps: photographing a high-definition PCB component sample, carrying out the data augmentation of the PCB component sample, marking various types of components in the PCB component sample, and obtaining a PCB component database; sending the PCB component training sample to a deep neural network for training until the deep learning network converges.

The publication WOZNIAK MICHAL ET AL: “A survey of multiple classifier systems as hybrid systems”, INFORMATION FUSION, ELSEVIER, US, vol. 16, Apr. 29, 2013 (2013Mar. 29), pages 3-17, XP028757975, ISSN: 1566-2535, DOI: 10.1016/J.INFFUS.2013.04.006 discloses what are known as multiple classifier systems, also referred to as ensemble methods or ensemble learning. In FIG. 4 WOZNIAK MICHAL ET AL disclose parallel, in other words also serial, topologies, in accordance with which the classifiers are arranged and are used.

### BRIEF SUMMARY AND DESCRIPTION

The scope of the embodiments is defined solely by the appended claims and is not affected to any degree by the statements within this summary. The present embodiments may obviate one or more of the drawbacks or limitations in the related art.

Embodiments provide an adjustment to any changes that take place during manufacture or influences on the manufacture of one or more circuit boards and to specify improved detection of defects during the manufacture of one or more circuit boards.

Embodiments provide a first aspect of a method for optical quality control during the manufacture of circuit boards.

Embodiments provide a second aspect of a device, for example an inspection system for manufacturing control of circuit boards, for the performance of the method in accordance with the first aspect.

Embodiments provide a third aspect by a computer program product with program code that if executed serve for the performance of the method in accordance with the first aspect.

### BRIEF DESCRIPTION OF THE FIGURES

FIG. 1 depicts a schematic representation of circuit board manufacture with a first form of embodiment of an inspection system for manufacturing control.

FIG. 2 depicts a schematic representation of circuit board manufacture with a second form of embodiment of an inspection system for manufacturing control according to an embodiment.

FIG. 3 depicts a schematic representation of an operational sequence of image processing and defect indicator determination for quality control during circuit board manufacture according to an embodiment.

FIG. 4 depicts a schematic representation of an operational sequence for (post-)training of an adaptive algorithm on the basis of a dataset containing diagnostic information according to an embodiment.

FIG. 5 depicts a schematic representation of a first operational sequence of image data processing for the training and during the use of a trained adaptive algorithm according to an embodiment.

FIG. 6 depicts a schematic representation of a second operational sequence of image data processing for the training and during of the use of a trained adaptive algorithm according to an embodiment.

FIG. 7 depicts multiple class activation maps for analysis as to which parts of an image influence a classification decision of an adaptive algorithm according to an embodiment.

FIG. 8 depicts a schematic representation of a method for quality control according to an embodiment.

FIG. 9 depicts a schematic representation of a method for quality control according to an embodiment.

FIG. 10 depicts a schematic representation of a method for training an adaptive algorithm according to an embodiment.

FIG. 11 depicts a schematic representation of a method according to an embodiment.

FIG. 12 depicts a schematic representation of a method according to an embodiment.

FIG. 13 depicts a schematic representation of a method according to an embodiment.

### DETAILED DESCRIPTION

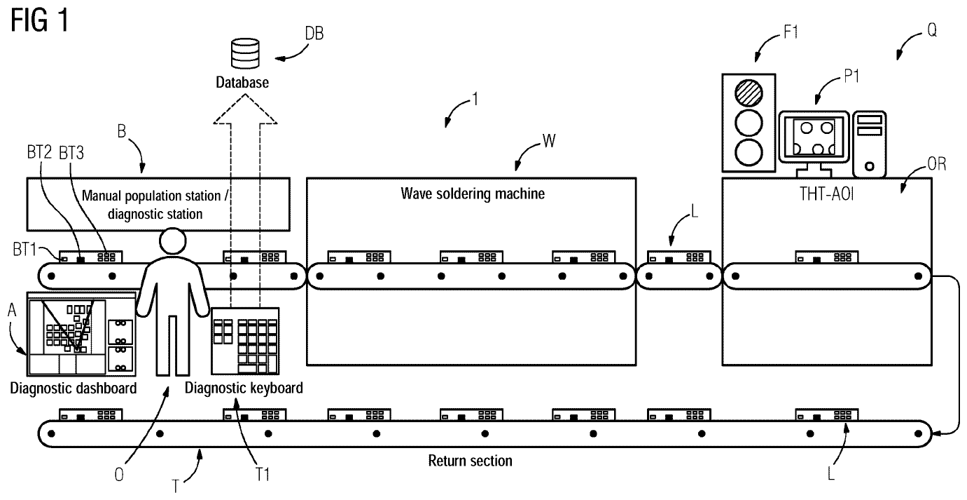

FIG. 1 depicts a facility 1 or a system for circuit board manufacture. The facility 1 includes a manufacturing line with an inspection system Q for quality control of the manufactured circuit board(s) L. The inspection system Q for quality control may be used during the manufacture of another product. For example, instead of the quality control of one or more circuit boards the use for surface testing, welding seam testing, deformation detection, and/or consignment tracking through to robot/machine vision is possible.

The facility 1 includes a population station B for populating the circuit board(s) with electrical or electronic components BT1, BT2, BT3. The facility 1 further includes a wave soldering machine W for the production of an electrically conductive connection between the circuit board and the electrical components BT1, BT2, BT3. After the soldering process the contact points (hereinafter referred to as soldering points) and the form thereof are optically inspected. In most cases use is made of automatic optical inspections, AOI.

However, as described in the introduction, the inspection system Q cannot react or be adjusted dynamically to changing conditions or influences during manufacture. Hence it is possible that the inspection system Q may indicate too many of the examined circuit boards L as defective, even though these circuit boards L are actually defect-free, so-called “false positives”. This in turn increases the number of follow-up inspections or diagnoses. Improving the detection of these “false positives” results in a reduction in the workload.

In FIG. 1 the first defect indicator F1, for example determined by optical image processing OR, is output via a display unit, such as for example a light signal system. For example, a light signal system may be provided that outputs a first light signal, such as for example red, if a defect has been determined by the inspection system Q, for example by optical image processing OR, i.e., a first defect indicator F1 indicates a defect or displays a second light signal if no defect has been detected, i.e., if a first defect indicator F1 does not indicate a defect.

The optical image processing OR, such as for example segmentation or pattern recognition or object recognition, serves for the classification of an image captured of the circuit board or of one or more image regions.

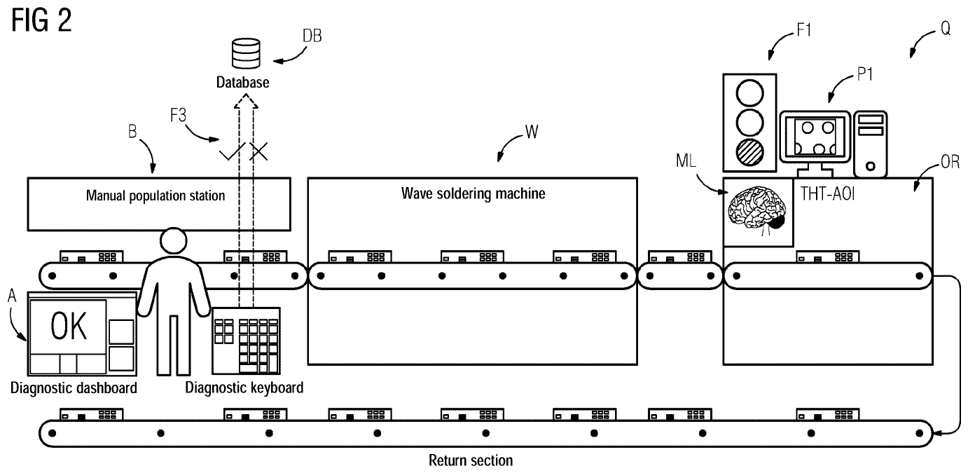

FIG. 2 depicts a facility 1 with an improved inspection system Q for quality control. The inspection system Q includes an adaptive algorithm ML which provides the quality control to be adapted to the changing (ambient) conditions or influences during manufacture.

By the adaptive algorithm ML, the inspection system Q makes use of the result of the diagnosis/diagnoses and makes it possible to reduce the effort entailed in (re)programming the software (modules) for optical image processing OR. The inspection system Q further provides an (automatic) improvement in quality control, in that for example (automatic) (post-)training of the adaptive algorithm ML takes place. In addition, the first pass yield may be increased, in that the soldering points are examined by the adaptive algorithm ML of the inspection system Q. The results of the adaptive algorithm ML may be passed to the software module, cf. software module SWM1 further below, for optical image processing OR. For example, the original evaluation of the soldering points may be overwritten by the software module for optical image processing OR. Thus, the result of the adaptive algorithm ML may be used instead of the result of the optical image processing OR as the (overall) result of the quality control. A follow-up inspection by the inspection system Q, such as for example a manual diagnosis, of one or more circuit boards L indicated by the optical image processing OR as defective is thus undertaken in advance by the adaptive algorithm ML. A manual diagnosis of the circuit board L by an operator O, for example via the return section, is not then required. Furthermore, the work of maintaining the inspection and test programs in a software module, cf. software module SWM1 further below, for optical image processing OR is obviated, the maintenance work being necessary for example because of changes in the light conditions or changes in the composition of the circuit board by the circuit board manufacturer.

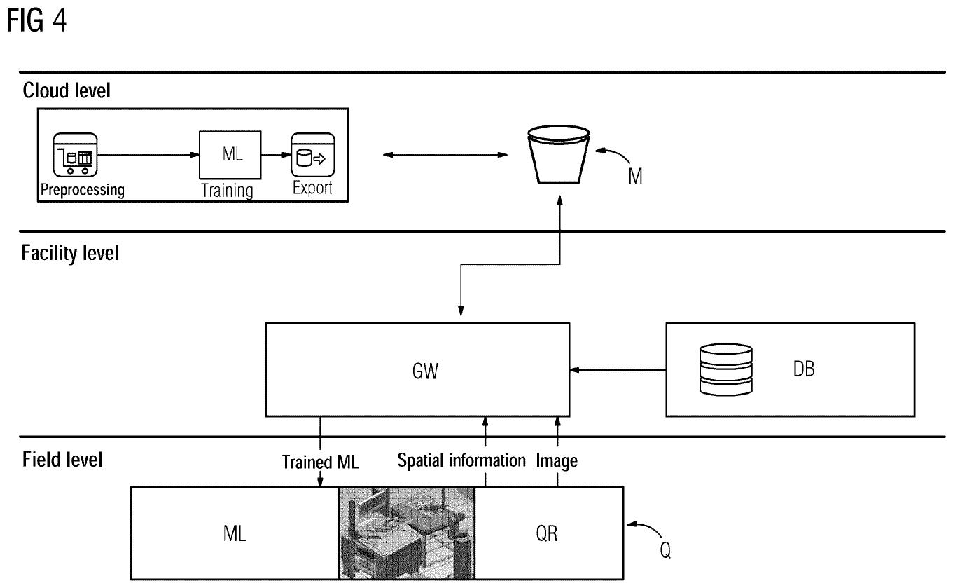

The adaptation, also called training, of an adaptive algorithm ML takes place in a training phase (cf. inter alia FIG. 4 and FIGS. 5 and 6), in which the adaptive algorithm ML receives images P1 of the circuit board L as input and changes internal parameters. The adaptive algorithm ML thus starts for example in a state in which it fails to solve a problem adequately, here the quality control of the circuit board(s). Thanks to the training the adaptive algorithm ML is specialized to the task. Not until after the training is the adaptive algorithm proficient in the set task, for example here the classification of an image or associated image data into one or more (defect) classes, this being referred to by data scientists as “prediction”.

For quality control of the circuit board L using a captured image of the circuit board, or the associated image data, which is for example present in the form of a file, use may be made of a defect indicator F1, F2, F3. A defect indicator F1, F2, F3 may indicate a defective or defect-free state of a circuit board L. For example, a first defect indicator F1 may be determined by the optical image processing OR and a second defect indicator F2 by the adaptive algorithm. Further, thanks to the diagnosis of a circuit board L (for example by the operator O) it is possible to determine a third defect indicator.

Defect categories and corresponding defect classes may be provided for this purpose. For example, a defect indicator F1, F2, F3 may indicate multiple different defective states, i.e., defects, of a circuit board L. Possible defects during the manufacture of a circuit board L are for example: Soldering paste is missing or is incompletely pressed, soldering paste smudged, adhesive is missing or is incompletely pressed, adhesive smudged, component is missing, component offset or twisted, gravestone effect, component transposed, color ring detection in the case of MELF components, positive materials detection for IC/uC types, positive materials detection for resistance value, component polarity reversed (IC, diode), short-circuits and solder bridges (IC, uC), soldering point missing, open THT soldering point, THT soldering point without through-contacting. A value of the defect indicator F1, F2, F3 may thus indicate the detected defect, also called the defect category. The value of the defect indicator may include an alphanumeric string of numbers or may include such a string. Further, the defect indicator may describe the defect in plain text, see above, or contain this in encoded form.

As described, the adaptive algorithm ML receives an image or one or more image regions as input and associates the image or the image region(s) to form one of the defect categories or to form a class corresponding to one of the defect categories. A defect class may thus represent one or more of the aforementioned defects. As mentioned previously, the defect indicator may also assume a value that indicates a defect-free state of the circuit board L.

One or more defects detected by the optical image processing OR may be passed to the adaptive algorithm ML. To this end, the adaptive algorithm ML expects an image, for example in the form of image data, for example in the form of an (image) file, and for example the spatial information as to the image region in which the defect or defects as per the optical image processing OR are located. The adaptive algorithm ML then sequentially evaluates each image or each image region anew. If all images or image regions have been evaluated, the adaptive algorithm ML provides the result for each image region, for example at a transfer point of the optical image processing OR. The results of the adaptive algorithm ML may now be used to overwrite the evaluation of the optical image processing. Of advantage in this case is a reduction in the programming work involved in the optical image processing OR and an increase in the first pass yield, since the adaptive algorithm ML, which for example is likewise situated on the inspection system Q, corrects the evaluation of the soldering points by the optical image processing OR.

As shown in FIG. 2, instead of the first defect indicator F1, which was determined by the optical image processing, the second defect indicator F2, which was determined by the adaptive algorithm ML, may be output. To this end, as described above a display unit such as a light signal system may be provided, that displays a first light signal, such as for example red, if a defect was determined (also) by the inspection system Q, for example by the adaptive algorithm ML, or displays a second light signal if no defect was detected, i.e., if the second defect indicator F2 does not indicate a defect.

A result of a diagnosis may be stored in a database DB by an operator O. In this case, a third defect indicator F3 may be used, that likewise as described may represent one or more defect categories (and of course also a defect-free state of a circuit board L). The third defect indicator F3 may then be used for (post-)training of the adaptive algorithm ML.

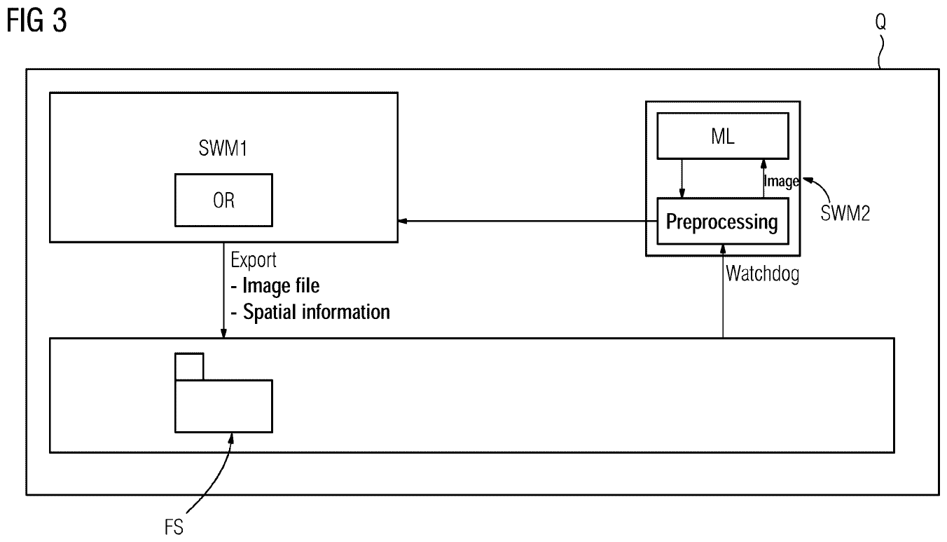

FIG. 3 depicts a schematic representation of an operational sequence of image processing and defect indicator determination for quality control during circuit board manufacture. The optical image processing OR and the adaptive algorithm ML are in this case implemented in a first or a second software module SWM1, SWM2. It may however also be the case that both the optical image processing OR and the adaptive algorithm ML are implemented in a (single) software module. The software module(s) may in this case be stored in the inspection system Q and/or may be executed by the inspection system Q.

In the present case a first defect indicator F1 is first determined by a first software module SWM1. The defect indicator F1 and the captured image are then stored in a memory FS, such as for example a distributed file system. In addition to the captured image P1, spatial information indicating the image region in which the defect(s) is/are located may be stored in the memory FS. The memory FS may in this case likewise be located on the inspection system Q.

All defects that are detected by the optical image processing OR are passed to the adaptive algorithm ML, for example in the form of one or more first defect indicators F1. The second software module SWM2 may for example retrieve the captured image P1 and the spatial information about the image region in which the defect(s) as per the optical image processing OR is/are located, from the memory FS. The adaptive algorithm ML then evaluates the transferred image or each transferred image region. The memory FS may be monitored, for example by a watchdog, such that as soon as a new image or a new image file is present, the processing by the second software module SWM2 or by the adaptive algorithm ML may be started.

Further, it may be necessary that before the adaptive algorithm ML processes an image P1 or image region, preprocessing of the image of the image region has to take place. This preprocessing, such as for example the scaling and padding of the image or of the image region may likewise take place by the second software module SWM2. Alternatively, a separate software module that performs this preprocessing, also called “data prep”, may be provided.

If an image or the one or more image regions were evaluated by the adaptive algorithm ML, the second software module SWM2 provides the result for the image or each image region at a transfer point of the first software module SWM1, for example in the form of a second defect indicator F2. The second defect indicator F2, which was determined by the adaptive algorithm ML, may alternatively or additionally be output by the second software module SWM2. Alternatively, a separate software module, which performs the result processing, may be provided. For example, the second defect indicator may likewise be stored in the memory FS, such as for example the aforementioned distributed file system.

The first software module SWM1 may now use the result in the form of one or more second defect indicators F2 of the adaptive algorithm ML, in order to overwrite the evaluation of the optical image processing OR or to output the result of the adaptive algorithm ML, i.e., instead of the result in the form of one or more first defect indicators F1 of the optical image processing OR.

FIG. 4 depicts a schematic representation of an operational sequence for (post-)training of an adaptive algorithm ML on the basis of a dataset for example containing image data, spatial information and diagnostic information.

For training or post-training of the adaptive algorithm ML images of circuit boards indicated as defective by the image processing OR by a first defect indicator F1 and for example the spatial information on the defects detected by the image processing OR are picked off and for example, as shown in FIG. 4, stored in a cloud, for example in the memory M shown in FIG. 4.

For this purpose, the inspection system Q may be connected to a gateway GW, the gateway producing a connection between the cloud and the inspection system Q. Moreover, the information from the manual diagnosis of the operator from the quality database DB may be stored in the memory M. For this purpose, the database DB may also be connected to the gateway GW. The diagnostic information, that for example is stored in the database DB, represents the knowledge of the operator O who was involved in the diagnosis of the circuit board(s) indicated as defective by the image recognition OR. This diagnostic information is used to label the images of the circuit board(s). In other words, the image captured of a circuit board and the spatial information about a defect determined by the image acquisition are linked to the diagnostic information and if appropriate stored in the memory M in the cloud. In the cloud the adaptive algorithm ML may then be trained on the basis of this data labeled with the diagnostic information. The images labeled with the diagnostic information then form the so-called “ground truth” for the adaptive algorithm. If appropriate, a preprocessing “data prep” of the received or stored images initially also takes place in the cloud. This preprocessing may for example include padding and augmentation of the images or image data, as is explained below.

On conclusion of the training, the adaptive algorithm may evaluate an image of a circuit board, for example using the “ground truth”—i.e., on the basis of images or image data labeled with diagnostic information. The diagnostic information may in this case be present in the form of a third defect indicator F3.

After the training the trained adaptive algorithm ML may be exported, cf. “Export” in FIG. 4. The trained adaptive algorithm ML may then be transferred to the inspection system Q. An adaptive algorithm ML already present in the inspection system Q may thus be updated by the newly trained adaptive algorithm ML. Consequently, the adaptive algorithm ML may be adjusted. For example, in the presence of a specified number of captured images and/or in the presence of a specified amount of diagnostic information it is possible to update the adaptive algorithm on the inspection system Q. The diagnostic information in this case for example corresponds to the third defect indicator, the value of which was established by an operator during the diagnosis.

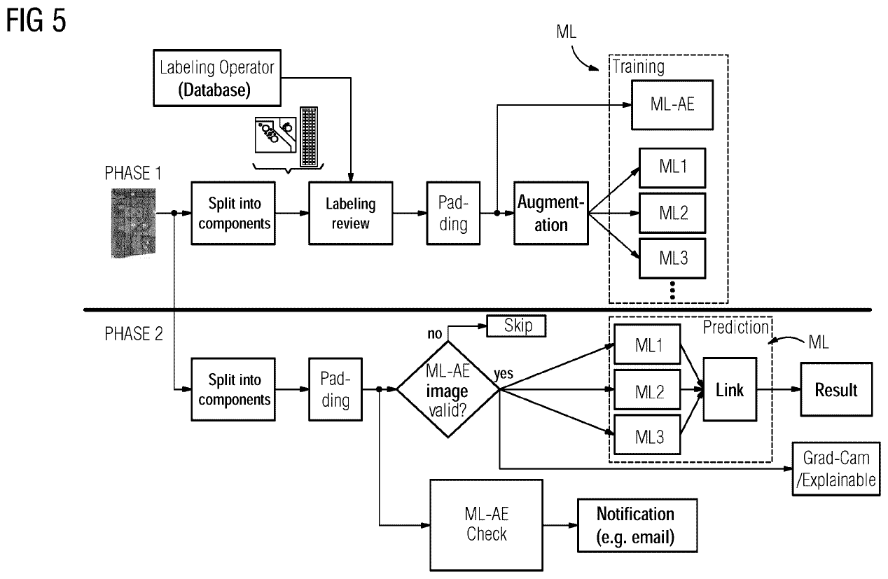

FIG. 5 depicts a schematic representation of a first operational sequence of image processing for the training (Phase 1) and during of the use of an adaptive algorithm ML (Phase 2).

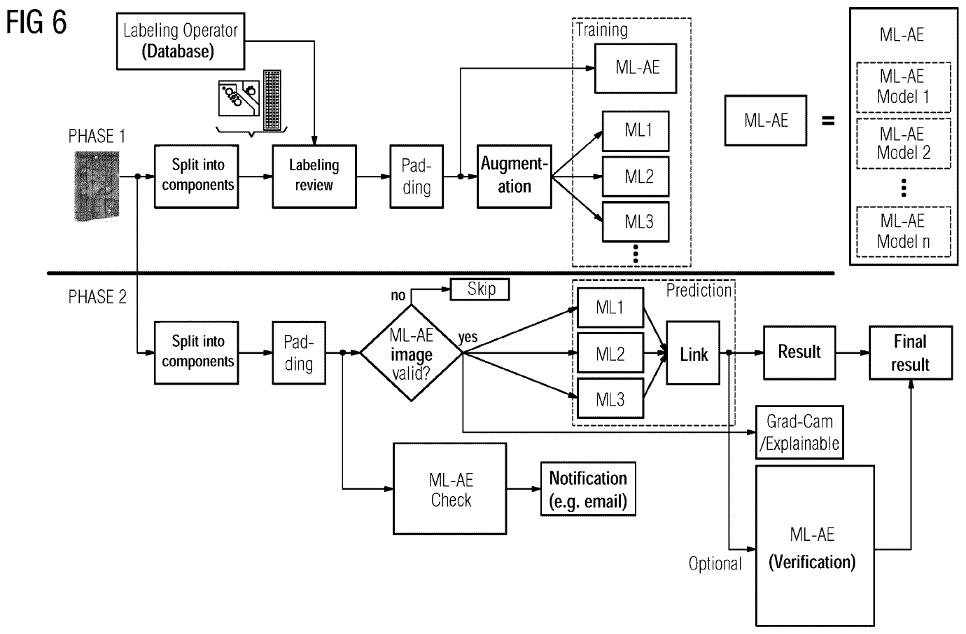

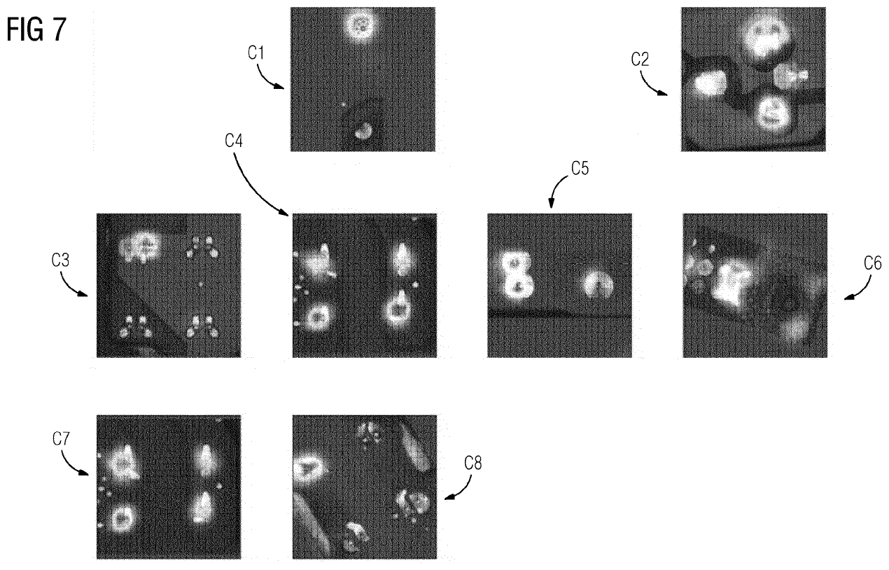

In order to obtain results from the adaptive algorithm ML, different phases and steps are performed, which are explained below. The basis for this is an image P1 captured by the circuit board L to be examined. This image P1 may be split into different so-called image regions, cf. image regions C1, . . . ,C8 in FIG. 7. This is referenced as “Split into components” in FIGS. 5 and 6.

In Phase 1 (training phase) it is necessary for the image or the image regions to be assigned to the present and defined defect categories. There exist various values of a defect indicator, which indicate a defective or a defect-free state of the circuit board L.

This assignment, also called “labeling”, takes place manually and using human expertise, for example by the images and the associated defect indicators stored in the database DB, these having been generated by an operator as a result of the diagnosis. If for example an image contains a particular defect A (for example a pin short-circuit), this is provided with the label A. This produces various groups of images. These images (image groups) are referred to as ground truth data and serve as the basis for the further training steps.

The labeling process may include two stages: the operator O performs a pre-labeling of the data and stores this information in the database DB. In addition, a review of the labeling carried out may be undertaken and the pre-labeling overwritten if appropriate. FIG. 5 depicts “Labeling review” by the “Labeling operator (database)”.

Because the individual images or image regions are of different sizes, in the next step it is necessary to bring the images or image regions to a uniform size. The different size of the images or image regions is physically conditioned, since the image regions contain different electronic components or test regions with one or more soldering points. For example, a uniform image size may be defined for processing. For example, a square-shaped size may be defined (for example 512 by 512 pixels may be selected). The uniform image size may be configurable, so that it is adjustable, for example to different test regions on a circuit board and thus different circuit board types. In order to achieve scaling to a uniform image size, an “up-down sampling” takes place for example and artificial pixels may be generated and artificial pixel values padded. This is known as padding. For example, if an image region has an original size of 200 by 600 pixels, artificial pixel values are generated and are appended to the image, in order for example to obtain a square-shaped size. The generated artificial pixel values may be randomly generated from a generated color distribution, for example permissible RGB values. The color distribution from which the pixel values for the artificial pixels are generated may for example be given by intervals in the RGB color space. The color distribution is in this case adjustable and should be in a similar color distribution to the basic color of the circuit boards. For example, an artificial pixel value may be selected, for example randomly, from an interval for the red channel, for example [37, 42], an interval for the green channel, for example [63, 73], and an interval for the blue channel, for example [36, 41]. The boundary values of the respective interval or color distribution in general may be determined using the minimum values and/or maximum values of captured images of different circuit boards, for example the aforementioned ground truth dataset. The generated color distribution or the color ranges from which the artificial pixel values for the padding are selected may correspond to the color values of the circuit boards from a dataset of images of the circuit board, for example from the circuit board manufacture in the facility.

Following on from the padding, an augmentation of the images or image region may take place. Alternatively, the augmentation may also take place first. The augmentation is a method to augment the original dataset of images in order to generate the maximum variance and to minimize the influence of noise and slight changes to new genuine images. The images or image regions are rotated, turned, mirrored randomly and/or individual RGB color channels are changed and/or the brightness of the images or image regions is varied for this purpose. This thus produces a plurality of new, synthetic images or image regions. This step is advantageous for the training of the adaptive algorithm and results in an improvement in the classification of the adaptive algorithm ML.

In the next step the adaptive algorithm ML is trained, for example using the augmented dataset of images or image regions. The adaptive algorithm may for example include two parts: the first part includes very many so-called convolution layers with very many parameters and the second part includes a fully-connected neural network, with fewer parameters. The training may then take place in two steps. First comes transfer learning. This means that the first part of the adaptive algorithm (convolution layers) has been pretrained on a known and large dataset. Only the second part (fully-connected network) may be trained (i.e. the parameters of the network are optimized using specific and known optimization methods). Following on from this, “fine-tuning” may take place. Here the complete adaptive algorithm is trained, but for example with a lower learning rate (i.e. a less strong adaptation or change in the parameters) and a shorter time (fewer epochs). Once the adaptive algorithm has been trained, it is able to classify new images and may thus be used in the “productive phase”.

One possible form of embodiment of the adaptive algorithm ML includes the interconnection of different models ML1, ML2, ML3 with the aim of improving the overall result (this is known as ensemble learning). In the case of the models ML1, ML2, ML3 adaptive algorithms may in turn be involved. The models ML1, ML2 or ML3 may be executed in two parts, as described above, or else one or more of the models ML1, ML2, ML3 may be executed in one part. In ensemble learning different models ML1, ML2, ML3 are trained with the same data. The models ML1, ML2, ML3 differ slightly in their structure or operating principle, but have the same aim: classification of the circuit boards in accordance with the defect categories or defect classes. For example, the models ML1, ML2, ML3 have different model architectures and/or different hyperparameters or values of the hyperparameters. The outputs of the individual models ML1, ML2, ML3 are linked to one another in order to improve the overall results. In the case of three models, for example, the end result is only used if two of the three models match. Consequently, greater trust is achieved, since trust is not placed solely on the result of a single model ML1, ML2, ML3.

Additionally, and/or alternatively to the models ML1, ML2, ML3 an autoencoder ML-AE (AE for short) may be trained, that serves to reconstruct the image or the image region obtained as input. Later on in productive operation in “Phase 2” the autoencoder AE may be used to test one or more newly captured images or image regions of the circuit board to see whether these are similar to the images, on the basis of which the adaptive algorithm, or for example the models ML1, ML2, ML3 of the adaptive algorithm, were trained. If a reconstruction error of the autoencoder AE for example exceeds a specified threshold value, this may serve as an indicator of a possibly defective classification of the adaptive algorithm. As represented in Phase 2 as “ML-AE Check”, a notification may then be given by email.

### Phase 2 (“Productive Phase”)

The adaptive algorithm ML may for example include an autoencoder ML-AE (AE for short). The autoencoder AE may, as described, be trained with the ground truth data in Phase 1 in order to carry out a validation of one or more new images, of one or more circuit boards, and if these are not valid, be stored for example in a directory intended for this purpose, for example in a memory on the inspection system or a database, and for example not be used for the prediction of a defect indicator by the adaptive algorithm. Further, the autoencoder AE may be used to monitor the new data (data distribution) in order to detect a drift in the (image) data. A drift would mean that something has changed in the images and that if appropriate a correction or other intervention is necessary. This calls for monitoring over the time of the new images by the autoencoder AE. A reconstruction error of the autoencoder AE may be used as a characteristic value for a drift of the new images.

The result of the adaptive algorithm ML may take place via a weighting of the results of the models ML1, M12, ML3. The result of the adaptive algorithm ML may be output in the form of a (second) defect indicator F2. Output here means stored, for example in a memory, such as for example in a file, or for example reproduced on a display unit.

In addition, as shown in FIG. 7, a heatmap or Grad-CAM (Gradient Class Activation Map) of the class prediction of the autoencoder AE may be output or displayed.

FIG. 6 depicts a schematic representation of a second operational sequence of image processing for the training and during the use of an adaptive algorithm ML. This operational sequence shown in FIG. 6 is largely identical to the one in FIG. 5 and differs only in the following features.

An additional evaluation of the classification result of the adaptive algorithm ML may take place, in that an autoencoder ML-AE Model 1, Model 2, . . . , Model n is trained per defect category or corresponding defect class (on the basis of the ground truth data). After the classification by the adaptive algorithm ML, the corresponding image is predicted by all available autoencoder models ML-AE Model 1, Model 2, . . . , Model n and the model with the fewest defects (reconstruction errors) corresponds to the defect class (this step is optional). Consequently, the result of the adaptive algorithm ML may be verified and if appropriate the result of the adaptive algorithm may be corrected into a “Final result”, which for example corresponds to that of the autoencoder ML-AE Model 1, Model 2, . . . , Model n with the fewest defects.

FIG. 7 depicts multiple class activation maps C1, . . . ,C8 for analysis as to which parts of an image influence a classification decision of an adaptive algorithm ML. A further element of the adaptive algorithm may be a so-called Grad-CAM (Gradient Class Activation Map). Consequently, it is possible to show which pixels in the image or image region were decisive for the classification result of the adaptive algorithm. For example, regions from the image that were crucial for the decision of the adaptive algorithm are characterized and these regions may be shown to an operator, so that the operator on the one hand has feedback about the operating principle of the adaptive algorithm and on the other hand may very quickly validate the result of the adaptive algorithm.

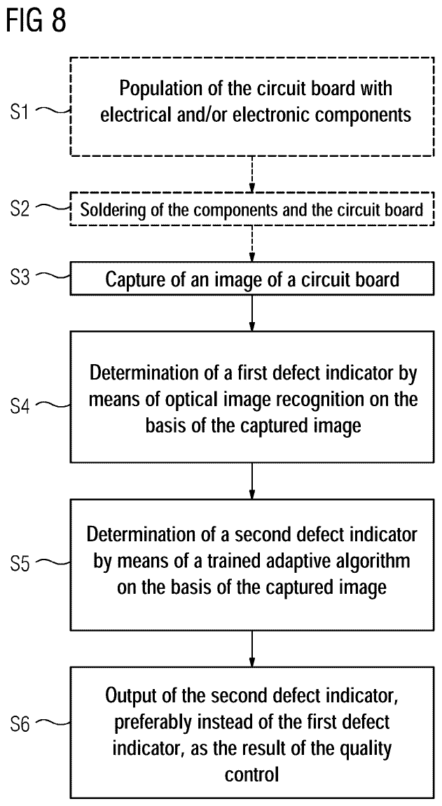

FIG. 8 depicts a schematic representation of a method for quality control in accordance with a first form of embodiment.

To this end, in a step S1 a circuit board is populated with electrical components. In a subsequent step S2 the components are connected to the circuit board, for example by soldering.

Soldering is a thermal method for positive substance joining of materials, wherein a liquid phase arises by melting of a solder (fusion soldering) or by diffusion on the boundary surfaces (diffusion soldering).

Wetting is an important criterion for successful soldering. Only so much solder should be used at the soldering point so that the contour of the component connections remains visible in the solder. The angle between a drop of the liquid solder and the basic material is called the wetting angle. A wetting angle of between 0 and 30° is classed as “completely to adequately wetted”, of between 30 and 90° as “partially wetted” and over 90° as “not wetted”. In principle the wetting angle should therefore be less than 30°.

A further quality feature is the cleanliness of the soldering points, so that for example no residual solder should be found outside the soldering points. The soldering points should be clean and uniform, which also applies for the through-holes.

In order if appropriate to establish defective soldering points, the circuit board is subjected to a quality control. Since during circuit board manufacture a plurality of circuit boards is produced, where appropriate a quality control of all soldered circuit boards or at least of some of the soldered circuit boards is necessary. For quality control purposes an image of a circuit board may be captured in a step S3. Using optical image processing a first defect indicator may be determined on the basis of the captured image.

The image acquisition takes place for example with a scanner unit, for example including a camera, such as for example a charge-coupled device (CCD) line camera with red-green-blue (RGB) color filter and a lighting unit such as for example a light-emitting diode (LED). The circuit board surface is for this purpose, for example, captured by a relative movement of the scanner unit and the circuit board. The camera in this case for example generates an image of the circuit board with a color depth of 3×8 bits. The captured image is for example high-resolution with 8101×5157 pixels. The image acquisition is carried out with a telecentric lens. This means that the rays of the LED lighting unit reflected by the circuit board fall in parallel into the lens of the CCD camera. The result of this is that the structures of the circuit board are acquired perpendicular to the lens without perspective distortion. Consequently, the circuit board is mapped as equally large regardless of its distance from the lens. The scanner unit moreover has a mirror system for shortening the focal length, wherein the circuit board and the scanner unit are arranged at a short distance from one another during the image acquisition process. Thanks to the shortening of the focal length the system is very compact. Consequently, the inspection system together with image acquisition may more easily be integrated into the manufacturing line. Furthermore, thanks to the selective illumination of a small region the lighting unit may have smaller dimensions. This saves energy costs and ensures less build-up of heat. Furthermore, cheap high-volume products may be used in the region of the camera, which mostly offer a better resolution than the expensive industrial cameras manufactured only in small quantities.

On the basis of the captured image a first defect indicator may be determined in a step S4 by optical image processing. Once the image of the circuit board has been captured, it is evaluated in image processing software, for example a first software module SWM1. In this case, the image processing software may be used to compare the captured actual state with the stored setpoint states and a percentage variance is calculated. To this end, test fields may be established on the circuit board. These test fields correspond to the image regions in which the soldering points to be tested are situated. These test fields are established at component level. Multiple soldering points may be situated within one test field. The individual soldering point coordinates are then defined within the test fields. Consequently, the testing may be performed at soldering point level. For the evaluation of a soldering point as defective or defect-free by a first defect indicator the RGB values within the test regions are then for example read out. Now with the help of various filters, the mean value of the RGB values of an image point on the soldering point may be calculated. These filters are applied to all image points on the soldering point. After this operation each pixel is assigned an RGB value. Subsequently an RGB threshold value is established. Using this threshold value the pixels above and below this may be categorized. The pixels that lie either above or below the defined threshold value may now be counted. After this step a total is produced in each case which describes the number of pixels that fall above and below the threshold value. In the last step of the testing by optical image processing a second threshold value for the total of the pixels is defined. If the previously formed total of pixels falls above or below the second threshold value, the soldering point fails.

The definition of the test fields and of the soldering point coordinates may be created by the user and is stored in one or more test plans. For example, a test plan may be created for each product variant, and may then be scalably used in the inspection system and the optical image processing. The reference to the correct positioning of the circuit board may take place using passer marks on the circuit board, which are detected by the image processing and create the coordinate system. Consequently, the soldering point coordinates are also actually located where the soldering points are to be expected. The origin of the coordinate system may for example be established in the top left corner of the image.

The result of step S4 is therefore a first defect indicator which indicates whether a defective or defect-free circuit board was detected using the optical image processing.

This defect indicator may be stored together with the captured image and if appropriate further information such as for example spatial information on the soldering point on the circuit board detected as defective. For example, as already described, a memory, for example a distributed file system, may be used for this purpose.

In a step S5 a second defect indicator may be determined by a trained adaptive algorithm on the basis of the captured image or image region. To this end, the captured image or the image region may serve as input for a trained adaptive algorithm. The trained adaptive algorithm classifies the image or the image region in accordance with the defect classes of the defect indicator and outputs this classification as a second defect indicator.

In this case, the first defect indicator may have the same or equivalent defect classes or defect categories as the second defect indicator. Additionally, it is possible for the defect classes of the first defect indicator to be a subset of the defect classes of the second defect indicator, i.e., that therefore the second defect indicator additionally has defect classes that cannot be acquired by the first defect indicator. Moreover, the possibility exists for the first defect indicator to have one or more defect classes that cannot be acquired by the second defect indicator, which the second defect indicator therefore does not have. The same applies for the third defect indicator.

In a step S6 the second defect indicator may be output, for example instead of the first defect indicator, as the result of the quality control. Once the first and second defect indicator are present, the inspection system may output the first and/or second defect indicator. For example only the second defect indicator is output. For example, it may be the case that the optical image processing of the inspection system mistakenly indicates a circuit board as defective, and the (trained) adaptive algorithm indicates the circuit board as defect-free. In this case the result of the adaptive algorithm should then be used as the result of the quality control, in order to prevent an (otherwise necessary) follow-up inspection of the circuit board. In the event that the adaptive algorithm too identifies a defective circuit board, a follow-up inspection of the circuit board becomes necessary.

If the optical image processing determines a circuit board to be non-defective, the adaptive algorithm is for example not executed. The circuit board may then continue to be manufactured, or used for delivery or incorporation into a device. Nor is a diagnosis by an operator then necessary.

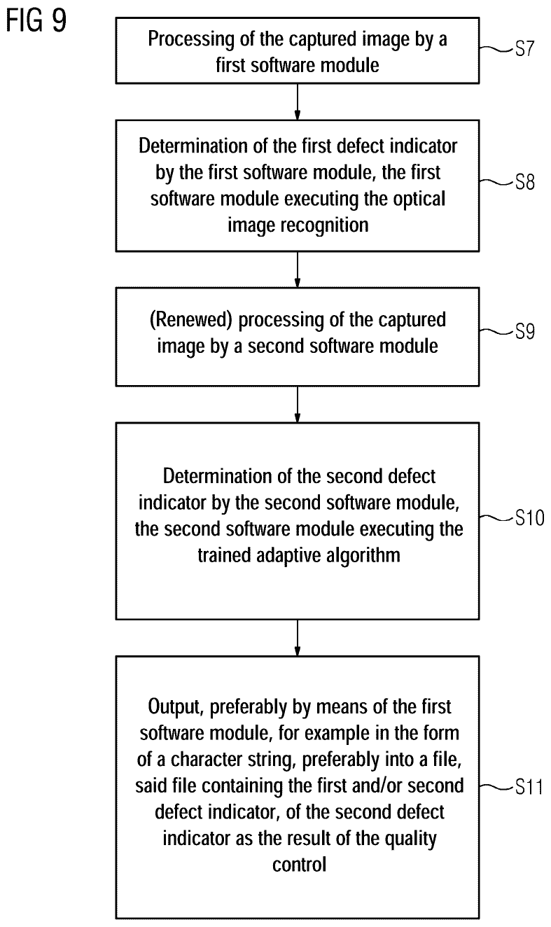

FIG. 9 depicts a schematic representation of a method for quality control in accordance with a second form of embodiment. In this case, the image captured of a circuit board, for example in step S3, is processed by a first software module. The first defect indicator is determined by the first software module. In this case, the optical image processing is also executed by the first software module. The first software module may further execute functions not described here.

A subsequent step S9 then entails (renewed) processing of the captured image by a second software module. Consequently, the second defect indicator may be determined by the second software module in a step S10. In this case, the second software module may execute the trained adaptive algorithm.

The first and the second software module may also be combined into a single software module. The first and second software module may be stored, for example in a memory, on the inspection system and/or for example executed by one or more processors of the inspection system.

In a step S11 the second defect indicator may then be output as the result of the quality control, for example by the first software module, for example in the form of a character string, for example into a file, the file containing the first and/or second defect indicator. Additionally, or alternatively the second defect indicator may for example be displayed. In FIG. 1 and FIG. 2 a display unit F1 or F2 is for example provided, via which the result of the quality control may be displayed, for example so as to be visible for an operator.

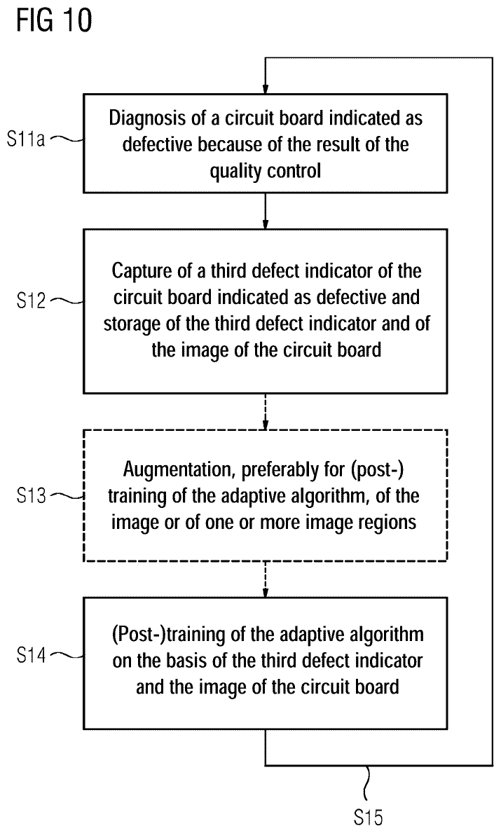

FIG. 10 depicts a schematic representation of a method for training an adaptive algorithm in accordance with a third form of embodiment.

Here a circuit board indicated as defective on the basis of the result of the quality control may be diagnosed (manually) in a first step S11a. The diagnosis corresponds to a follow-up inspection of the circuit board, for example in the event that this was detected as defective by the inspection system. The diagnosis may in this case be performed by an operator as described. The operator may input the result of his/her diagnosis via a diagnostic keyboard, as shown in FIGS. 1 and 2. Consequently, in a step S12 a third defect indicator may be determined and stored, for example in a quality database, i.e., database DB in FIGS. 1, 2 and/or 4. A further, third defect indicator for a circuit board initially indicated as defective by the optical image processing is therefore stored. Further, in step S12 the image of the circuit board may be stored. The third defect indicator may in this case be assigned or assignable to the image. For example, the result of the diagnosis in step 11a may be that the circuit board is actually defect-free, but that the optical image processing has mistakenly detected it as defective.

The steps S11a and S12 may be repeated multiple times, for example until a specified number of images is present, in which the diagnosis has produced a defect-free circuit board.

In an optional step S13 augmentation is possible, for example for the (post-)training of the adaptive algorithm, of the image or of one or more image regions. The augmentation in this case serves to generate synthetic images, in order to increase the number of images used to train the adaptive algorithm.

In a step S14 the (post-)training of the adaptive algorithm may then take place on the basis of the third defect indicator and the image or the augmented images of the circuit board.

In accordance with a step S15, step S11a may then again be executed, in order to obtain images for the renewed (post-)training of the adaptive algorithm and for example to increase the first-pass yield during the manufacture of the circuit boards.

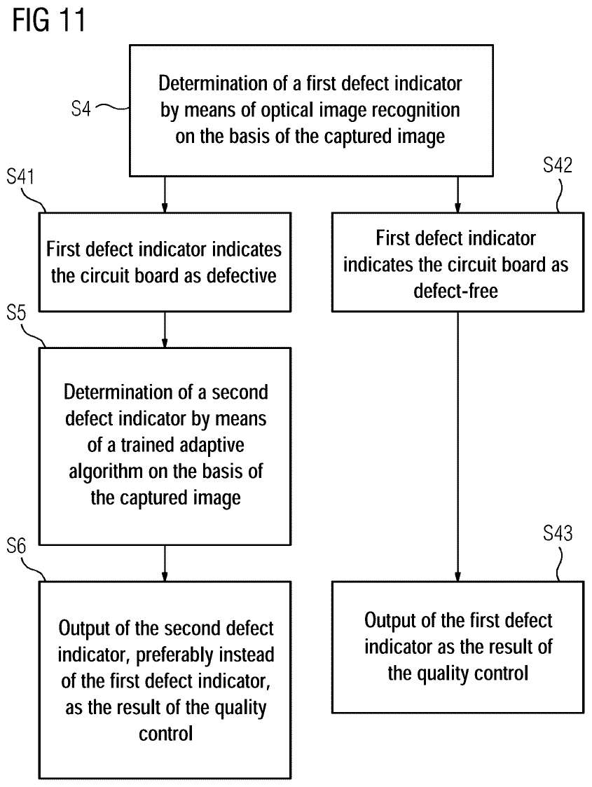

FIG. 11 depicts a schematic representation of a method in accordance with a fourth form of embodiment. In a step S4 the determination of a first defect indicator by optical image processing may take place as described on the basis of the captured image. As a function of whether the first defect indicator indicates the circuit board as defective or defect-free, the quality control is then continued.

If the first defect indicator in accordance with step S41 indicates the circuit board as defective, in a step S5 a second defect indicator is determined by a trained adaptive algorithm on the basis of the captured image. Then as described in a step S6 the second defect indicator is output, for example instead of the first defect indicator, as the result of the quality control. The output may in this case take place into a file or in the form of a visual display.

If the first defect indicator in accordance with step S42 indicates the circuit board as defect-free, then in an if appropriate immediately subsequent step S43 the first defect indicator is output as the result of the quality control.

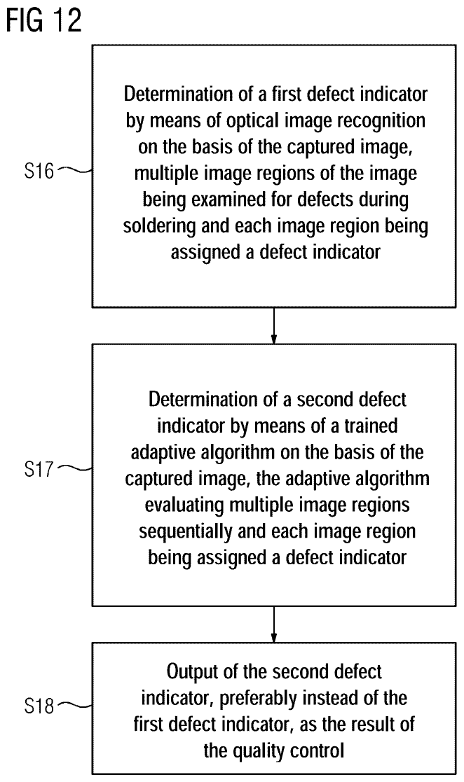

FIG. 12 depicts a schematic representation of a method in accordance with a fifth form of embodiment. In a step S16 a first defect indicator may be determined by optical image processing on the basis of the captured image, wherein multiple image regions of the image are examined for defects, for example during soldering, and each image region is assigned a defect indicator. An image captured of the (entire) circuit board may be split into multiple image regions. In this case, an image region may include one or more soldering points. Further, an image region may correspond to one or more test fields, in which the soldering points to be tested are situated.

In a step S17 a second defect indicator may be determined by a trained adaptive algorithm on the basis of the captured image, wherein the adaptive algorithm evaluates multiple image regions sequentially and each image region is assigned a defect indicator.

In a step S18 the second defect indicator or one of the second defect indicators may be output, for example instead of the first defect indicator, as the result of the quality control.

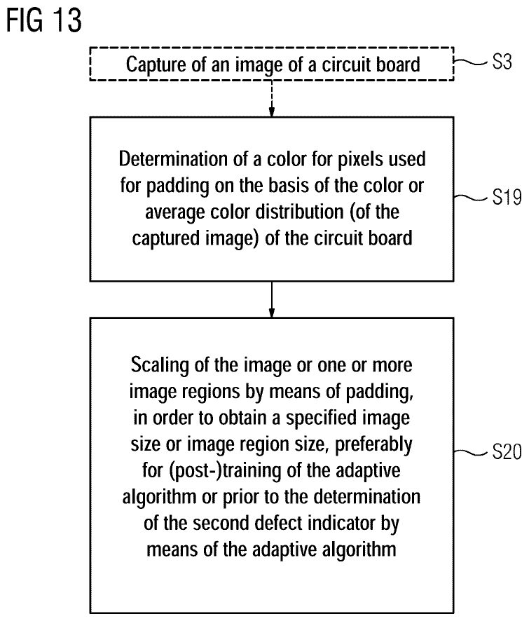

FIG. 13 depicts a schematic representation of a method in accordance with a sixth form of embodiment. As described, in a step S3 an image of a circuit board may be captured. In a step S19 a color for pixels to be used for padding may be determined on the basis of the color or average color distribution (of the captured image) of the circuit board.

In a step S20 the image or one or more image regions may be scaled by padding, in order to obtain a specified image size or image region size, for example for (post-)training of the adaptive algorithm or prior to the determination of the second defect indicator by the adaptive algorithm.

The proposed computer program product may have program code that if executed serve for the performance of the method in accordance with one or more of the steps S1 to S29. In this case, the computer program product may for example be stored on an inspection system and/or may be executed by this. For example, the computer program product may include the first and/or (only) the second software module SWM1 or SWM2.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for optical quality control (Q) during the manufacture (1) of circuit boards (L), comprising:
capture (S3) of an image (P1) of a circuit board (L), and determination (S4) of a first defect indicator (F1) by means of optical image processing on the basis of the captured image,
determination (S5) of a second defect indicator (F2) by means of a trained adaptive algorithm (ML) on the basis of the captured image (P1), and
wherein if the first defect indicator (F1) determined by means of the optical image processing (OR) indicates the circuit board (L) as defective (S41), the second defect indicator (F2) is determined (S5) by means of the trained adaptive algorithm (ML),
output (S6) of the second defect indicator (F2) instead of the first defect indicator (F1) as the result of the quality control (Q).

2. The method as claimed in the preceding claim, further comprising:
processing (S7) of the captured image (P1) and determination (S8) of the first defect indicator by a first software module (SWM1) which executes the optical image processing (OR), and processing (S9) of the captured image (P1) and determination (S10) of the second defect indicator (F2) by a second software module (SWM2) which executes the trained adaptive algorithm (ML), wherein for example the captured image (P1) is stored, preferably in the form of image data, particularly preferably in the form of an image file, in a distributed file system.

3. The method as claimed in one of the preceding claims, further comprising:
output (S11), for example in the form of a character string, preferably into a file, said file containing the first and/or second defect indicator (F1, F2), of the second defect indicator (F2) as the result of the quality control (Q), preferably by means of the first software module (SWM1).

4. The method as claimed in one of the preceding claims, further comprising:
diagnosis (S11) of a circuit board (L) indicated as defective because of the result of the quality control (Q), and capture (S12) of a third defect indicator (F3) of the circuit board (L) indicated as defective and storage of the third defect indicator and of the image (P1) of the circuit board (L),
(post-)training (S14) of the adaptive algorithm (ML) on the basis of the third defect indicator (F3) and the image (P1) of the circuit board (L).

5. The method as claimed in one of the preceding claims, further comprising:
repeated, preferably periodic, execution of the steps of at least one of the preceding claims (S15), for example until a specified first-pass yield quote is achieved, in order for example to capture changed conditions during the manufacture of the circuit board(s) (L).

6. The method as claimed in one of the preceding claims, further comprising:
wherein if the first defect indicator (F1) determined by means of the optical image processing (OR) indicates the circuit board (L) as defect-free (S42),
the determination of the second defect indicator (F2) by means of the trained adaptive algorithm (ML) is not executed (S43).

7. The method as claimed in one of the preceding claims, further comprising:
population (S1) of the circuit board (L) with electrical and/or electronic components (BT1, BT2, BT3), for example at a population station (B),
soldering (S2) of the components (BT1, BT2, BT3) to the circuit board (L), for example by means of a wave soldering machine (W).

8. The method as claimed in one of the preceding claims, further comprising:
determination (S16) of a first defect indicator (F1) by means of optical image processing (OR) on the basis of the captured image (P1), wherein multiple image regions (C1, . . . , C8) of the image are examined for defects, preferably during soldering, and each image region (C1, . . . , C8) is assigned a defect indicator.

9. The method as claimed in one of the preceding claims, further comprising:
determination (S17) of a second defect indicator (F2) by means of the trained adaptive algorithm (ML) on the basis of the captured image (P1), wherein the adaptive algorithm (ML) evaluates multiple image regions (C1, . . . , C8) sequentially and each image region (C1, . . . , C8) is assigned a defect indicator.

10. The method as claimed in one of the preceding claims, further comprising:
scaling (S20) of the image or one or more image regions by means of padding, in order to obtain a specified image size or image region size, preferably for (post-)training of the adaptive algorithm (ML) or prior to the determination of the second defect indicator (F2) by means of the adaptive algorithm (ML),
wherein preferably a color of the pixels used for padding is determined (S19) on the basis of the color or average color distribution of the circuit board (L).

11. The method as claimed in one of the preceding claims, further comprising:
augmentation (S13), preferably for (post-)training of the adaptive algorithm (ML), of the image (P1) or the image regions (C1, . . . , C8).

12. The method as claimed in one of the preceding claims, wherein the adaptive algorithm (ML) comprises a first and a second trainable part, and wherein the second part is (post-)trained using the third defect indicator (F3), wherein preferably the adaptive algorithm (ML) is used for the determination of the second defect indicator by means of the Ensemble Learning adaptive algorithm.

13. The method as claimed in one of the preceding claims, wherein by means of at least one autoencoder (AE), preferably one autoencoder per defect category, the captured image (P1) or the image region (C1, . . . , C8) is reconstructed, and that if a reconstruction error of the autoencoder falls above a threshold value, the image (P1) or the image region (C1, . . . , C8) is not used for the determination of the second defect indicator (F2) by means of the adaptive algorithm, and that preferably a diagnosis of the circuit board is performed, in order for example to determine a third defect indicator (F3).

14. A device, in particular an inspection system for quality control (Q) of circuit boards, for the performance of the method as claimed in one of the preceding claims.

15. A computer program product with program code means, which if they are executed serve for the performance of the method as claimed in one of the preceding claims 1 to 13.
